(19) United States
(12) Patent Application Publication
(10) Pub. No.: US 2011/0011732 A1
(43) Pub. Date: Jan. 20, 2011

(54) METHOD OF REPAIRING A MOLDING DIE FOR MOLDING GLASS

(76) Inventors: Chun-Yan Zhang, Suzhou Industrial Park (CN); Tsung-Hsien Lin, Suzhou Industrial Park (CN); Yung-I Chen, Taipei City (TW); Chao-Chi Chang, Suzhou Industrial Park (CN)

Correspondence Address: SINORICA, LLC, 2275 Research Blvd., Suite 500, ROCKVILLE, MD, 20850, US

(21) Appl. No.: 12/893,238

(22) Filed: Sep. 29, 2010

Related U.S. Application Data
(62) Division of application No. 11/875,905, filed on Oct. 20, 2007.

(51) Int. Cl. B23P 6/00; C23C 14/34

(52) U.S. Cl. 204/192.1

(57) ABSTRACT

The present invention provides a method of repairing a molding die for molding glass, the molding die for molding glass comprising a base member, a first buffer layer on the base member, which is made of titanium or any material which is easily attacked by a first attack solution, wherein the first attack solution includes hydrofluoric acid, a protective film on the first buffer layer; the method comprising the steps of using the first attack solution to remove the first buffer layer that causes no damage on the base member, and then operating a sputtering process to build a new first buffer layer and a new protective layer on the base member.

This is a divisional application of Ser. No. 11/875,905 filed on Oct. 20, 2007.

### BACKGROUND OF THE INVENTION

1. Field of the Invention

The present invention relates generally to glass molding, and more particularly to a method of repairing a molding die for molding glass.

2. Description of the Related Art

Typically, a conventional molding die for molding glass includes a base member and a protective film on the base member. Some molding dies are further provided with a buffer layer between the base member and the protective film for advantage of adhesion of protective film and easy for molding. Typically, the base member is made of stainless, silicon carbide, and wolfram carbide (WC) and the like, and the protective film is made of hard ceramics including non-crystallized carbon, silicon carbide, and silicon nitride, and noble metal film including platinum-iridium (Pt-Ir) alloy series, or iridium (Ir) alloy or ruthenium (Ru) alloy, or platinum-iridium (Pt-Ir) alloy or iridium-ruthenium (Ir-Ru) alloy added with chromium nitride (CrN), tantalum nitride (TaN), other nitrides, or aluminum oxide, and the like.

There are some issues in manufacture and design of the molding core for molding glass, including: 1) avoiding reaction and adhesion of glass; 2) enough hardness and strength to avoid the glass from being scraped; 3) high stability in high temperature to avoid decomposing and reaction in molding; 4) high heat resistance for heat recycling in molding; 5) well processing time and cost to form a specific optical surface; and 6) longer life time to lower the cost.

In practice, however, all of the conventional molding dies include a protective film, which is made of noble metal by sputtering, so that the cost is very high. When the protective film is damaged, it has to be removed by precision process and replace a new one that the molding die may reuse. The cost of replacing the new protective film is almost as same as a new molding die.

In addition, a conventional method of repairing the molding die with damaged protective film is limited to carbon protective film. The carbon protective film will be removed by plasma etching. The silicon buffer layer under the protective film will be damaged in etching process so that it has to be polished in another process. In a case of using noble metal, which is inactive, to be the buffer layer on the base member and ceramics to be the protective film, the damaged protective film will be removed by acid or alkali for replacing a new one. However, if both of the protective film and the buffer layer were damaged, they would have to be removed and it has to make sure that the base member will not be damaged in removing process.

### SUMMARY OF THE INVENTION

The primary objective of the present invention is to provide a method of repairing a molding die for molding glass, which has lower cost and high precision for molding precision glass.

According to the objective of the present invention, a method of repairing a molding die for molding glass, the molding die for molding glass comprising a base member, a first buffer layer on the base member, which is made of titanium or any material which is easily attacked by a first attack solution, wherein the first attack solution includes hydrofluoric acid, a protective film on the first buffer layer; the method comprising the steps of using the first attack solution to remove the first buffer layer that causes no damage on the base member, and then operating a sputtering process to build a new first buffer layer and a new protective layer on the base member

### BRIEF DESCRIPTION OF THE DRAWINGS

FIG. 1 is a sketch diagram of a first preferred embodiment of the present invention;

FIG. 2 is a sketch diagram of a second preferred embodiment of the present invention;

FIG. 3 is a flow chart of a method of repairing the molding die of the present invention; and

FIG. 4 is a flow chart of another method of repairing the molding die of the present invention.

### DETAILED DESCRIPTION OF THE INVENTION

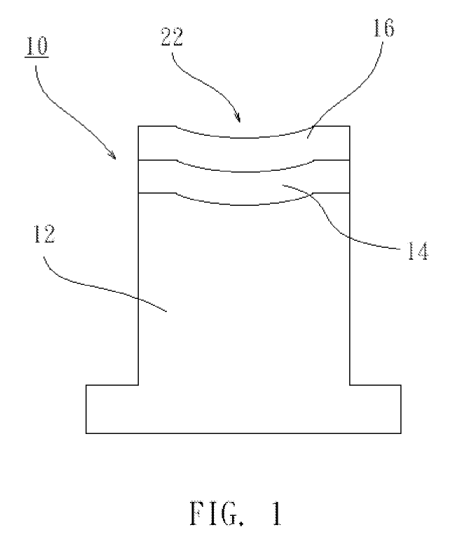

As shown in FIG. 1, a molding die 10 of the first preferred embodiment of the present invention includes a base member 12, which is made of hard material such as wolfram carbide (WC), a first buffer layer 14, which is provided on the base member 12 by sputtering for a thickness of 0.03 micrometer to 0.25 micrometer. The first buffer layer 14 is made of a material, such as titanium, that is easily attacked by a first attack solution. The first attack solution may be hydrofluoric acid of 20˜40 percent in volume. The molding die 10 further includes a protective film 16, which is provided on the first buffer layer 14 by sputtering. A composition of the protective film 16 includes platinum (Pt)-iridium (Ir) alloy, iridium (Ir)-rhenium (Re) alloy, tantalum (Ta)-ruthenium (Ru) alloy, molybdenum (Mo)-ruthenium (Ru) alloy, molybdenum (Mo)-rhenium (Re) alloy, or molybdenum (Mo)-hafnium (Hf) alloy. In the present invention, it's an iridium (Ir)-rhenium (Re) alloy with 80%˜85% iridium, and the thickness of the protective film is 0.1 micrometer to 1.0 micrometer. The protective film 16 has a molding surface 22, which is a recess, for molding glass. The first buffer layer 14 may help adhesion of the protective film on the base member 12 to prolong the molding die's 10 life.

We had a test on the attacking power of the first attack solution (hydrofluoric acid solution) on the first buffer layer 14, and the result is shown in the following table.

TABLE 1

| | |
|---|---|
| First attack solution | Time of |

| HF percent in volume | H₂O percent in volume | stripping |
|---|---|---|
| 40 vol. % | 60 vol. % | 1 hour |
| 27 vol. % | 73 vol. % | 3 hours |
| 20 vol. % | 80 vol. % | 4 hours |

Referring to the table, a thickness of the first buffer layer 14 is about 0.05 micrometer and the protective film 16 is 0.25 micrometer. The composition of the protective film 16 is iridium:rhenium=85:15. We choose K-VC89 glass manufactured by Sumita Optical Glass Inc. to be molded by the molding die 10 of the present invention to mold lenses for five hundred times, and then the first attack solution (20 vol. % hydrofluoric acid) is used to attack the first buffer layer 14 for four hours to remove the first buffer layer 14 and let the protective film 16 to separate from the bas member 12. There is no damage on the base member 12. After that, we provide a new protective film 16 and first buffer layer 14 on the base member 12 again, and operate another five hundred times molding processes. The result shows that the first buffer layer 14 is removed, the protective film 16 separates, and no damage on the base member 12.

With the result above, the concentration of hydrofluoric acid in the first attack solution determines the attacked rate of the first buffer layer 14. After the first buffer layer 14 has been removed, the protective film 16 will separate from the base member 12 to complete the stripping operation. The chemical reaction is hereunder:

Ti+2HF→TiF₂+H₂↑

When the composition of the protective film 16 is iridium:rhenium=50:50, and molding K-VC89 glass manufactured by Sumita Optical Glass Inc. by the molding die 10 of the present invention to mold lenses for a thousand times, and then the first attack solution (20 vol. % hydrofluoric acid) is used to attack the first buffer layer 14 for two hours to remove the first buffer layer 14 and let the protective film 16 to separate from the bas member 12. There is no damage on the base member 12. After that, we provide a new protective film 16 and first buffer layer 14 on the base member 12 again, and operate another 1,000 times molding processes. After four turns of stripping operations and repairs, the molding die 10 of the present invention may operate the molding processes over five thousand times.

When the base member 12 is sunk in the first attack solution (with 40 vol. % hydrofluoric acid) for fifteen days, we observe the base member 12 under a microscope and find there is no damage on the base member 12 which tells that the first attack solution will not attack the base member 12. When the base member 12 is made of wolfram carbide and is coated with 0.2 micrometer chromium (Cr), or 0.15 micrometer nickel (Ni), or 0.24 micrometer molybdenum (Mo), 0.16 micrometer rhenium (Re). Such base member 12 is sunk in the first attack solution (with 20 vol. % hydrofluoric acid) for four hours. We observe the base member 12 under a microscope and find there is no damage on the base member 12 which tells that the first attack solution will not attack any metal except titanium (Ti).

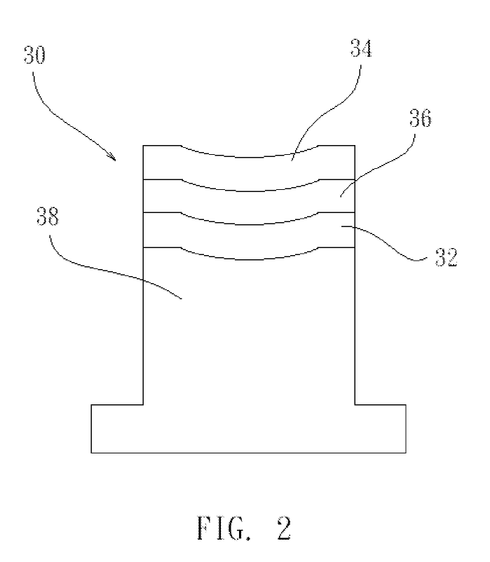

FIG. 2 shows a molding die 30 of the second preferred embodiment of the present invention, which is basically as same as the molding die 10 of the first embodiment, except that there is a second buffer layer 36 between the first buffer layer 32 and the protective film 34. The second buffer layer 36 is made by sputtering and is made of chromium (Cr), molybdenum (Mo), rhenium (Re), nickel (Ni), or any material which is easily attacked by a second attack solution. A thickness of the second buffer layer 36 is about 0.1 micrometer. The second attack solution includes 6 wt. % (NH₄)₂Ce(NO₃)₆ and 6 vol. % nitric acid. The protective film 34, which composition is molybdenum (Mo):ruthenium (Ru)=38:62 and thickness is 0.6 micrometer, is provided on the second buffer layer 36 by sputtering.

When the molding die 30 is attacked by the second attack solution for thirty minutes, the second buffer layer 36 is removed and the protective film 34 separates from the base member 38, and the first buffer layer 32 is still on the base member 38 to protect it, and then the first attack solution (40 vol. % hydrofluoric acid) is used again to remove the first buffer layer 32. The attacking time of the first attack solution is about five minutes and there is no damage on the base member 38. With this way (using the first and second attacking solutions), it could reduce the time of removing the first and second buffer layers 32, 36 and the protective film 34 that may operate the following repairing methods.

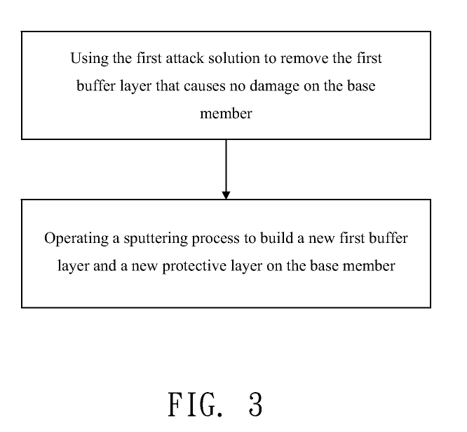

Referring to FIG. 3, a method of repairing the molding die 10 of the first preferred embodiment of the present invention includes the following steps. The first step is using the first attack solution to remove the protective film 16. The first attack solution will not cause any damage on the first buffer layer 14 and the base member 12. The next step is using sputtering to provide a new protective film 16 on the first buffer layer 14 to have a repaired molding die 10.

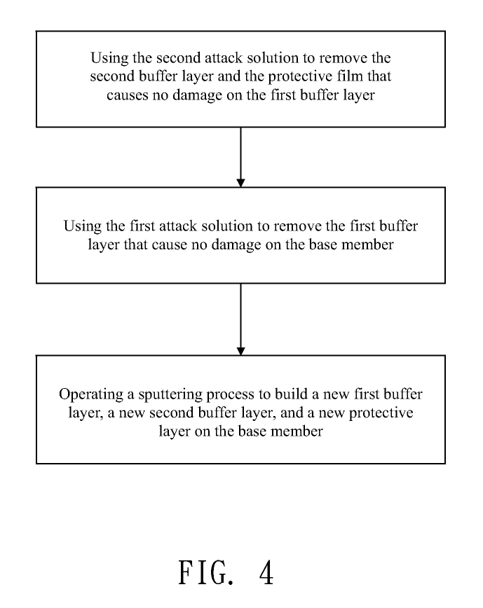

Referring to FIG. 4, a method of repairing the molding die 30 of the second preferred embodiment of the present invention includes the following steps. The first step is using the second attack solution to remove the protective film 34 and the second buffer layer 36. The second attack solution will not attack the first buffer layer 32 in this step. The next step is using the first attack solution to remove the first buffer layer 32, and finally using sputtering to rebuild a new first buffer layer 32, protective film 34, and second buffer layer 36 in order on the base member 38 to have a repaired molding die 30.

In conclusion, the present invention provides a novel molding die for molding glass, and the molding die may be repaired when the protective film is damaged. It could reduce the cost and keeps the high precision to mold glass.

The description above is a few preferred embodiments of the present invention and the equivalence of the present invention is still in the scope of the claim of the present invention.

What is claimed is:

1. A method of repairing a molding die for molding glass, the molding die for molding glass comprising a base member, a first buffer layer on the base member, which is made of titanium or any material which is easily attacked by a first attack solution, wherein the first attack solution includes hydrofluoric acid, a protective film on the first buffer layer; the method comprising the steps of using the first attack solution to remove the first buffer layer that causes no damage on the base member, and then operating a sputtering process to build a new first buffer layer and a new protective layer on the base member.

2. A method of repairing a molding die for molding glass, the molding die for molding glass comprising a base member, a first buffer layer on the base member, which is made of titanium or any material which is easily attacked by a first attack solution, wherein the first attack solution includes hydrofluoric acid, a protective film on the first buffer layer, a second buffer layer between the first buffer layer and the protective film, which is made of a material that is easily attacked by a second attack solution, wherein the second attack solution includes (NH₄)₂Ce(NO₃)₆; the method comprising the steps of using the second attack solution to remove the second buffer layer and the protective film that causes no damage on the first buffer layer and the base member, and then using the first attack solution to remove the first buffer layer that cause no damage on the base member, and then operating a sputtering process to build a new first buffer layer, a new second buffer layer, and a new protective layer on the base member.
